(19) United States
(12) Patent Application Publication
(10) Pub. No.: US 2013/0217239 A1
(43) Pub. Date: Aug. 22, 2013

(54) FLOWABLE SILICON-AND-CARBON-CONTAINING LAYERS FOR SEMICONDUCTOR PROCESSING

(71) Applicants: Abhijit Basu Mallick, Palo Alto, CA (US); Nitin K. Ingle, San Jose, CA (US)

(72) Inventors: Abhijit Basu Mallick, Palo Alto, CA (US); Nitin K. Ingle, San Jose, CA (US)

(73) Assignee: Applied Materials, Inc., Santa Clara, CA (US)

(21) Appl. No.: 13/589,528

(22) Filed: Aug. 20, 2012

Related U.S. Application Data
(60) Provisional application No. 61/536,380, filed on Sep. 19, 2011.
(60) Provisional application No. 61/532,708, filed on Sep. 9, 2011.
(60) Provisional application No. 61/550,755, filed on Oct. 24, 2011.
(60) Provisional application No. 61/567,738, filed on Dec. 7, 2011.

(51) Int. Cl. H01L 21/02

(52) U.S. Cl. CPC H01L 21/02274
USPC 438/778

(57) ABSTRACT

Methods are described for forming and curing a gapfill silicon-and-carbon-containing layer on a semiconductor substrate. The silicon and carbon constituents may come from a silicon-and-carbon-containing precursor excited by a radical hydrogen precursor that has been activated in a remote plasma region. Exemplary precursors include 1,3,5-trisilapentane (H₃Si—CH₂—SiH₂—CH₂—SiH₃) as the silicon-and-carbon-containing precursor and hydrogen (H₂) as the hydrogen-containing precursor. The hydrogen-containing precursor may also be a hydrocarbon, such as acetylene (C₂H₂) or ethylene (C₂H₄). The hydrogen-containing precursor is passed through a remote plasma region to form plasma effluents (the radical hydrogen precursor) which are flowed into the substrate processing region. When the silicon-and-carbon-containing precursor combines with the plasma effluents in the substrate processing region, they form a flowable silicon-carbon-and-hydrogen-containing layer on the semiconductor substrate.

### CROSS-REFERENCES TO RELATED APPLICATIONS

This application claims the benefit of U.S. Provisional Application No. 61/536,380, filed Sep. 19, 2011, and titled “FLOWABLE SILICON-AND-CARBON—CONTAINING LAYERS FOR SEMICONDUCTOR PROCESSING.” This application also claims the benefit of U.S. Provisional Application No. 61/532,708 by Mallick et al, filed Sep. 9, 2011 and titled “FLOWABLE SILICON-CARBON-NITROGEN LAYERS FOR SEMICONDUCTOR PROCESSING.” This application also claims the benefit of U.S. Provisional Application No. 61/550,755 by Underwood et al, tiled Oct. 24, 2011 and titled “TREATMENTS FOR DECREASING ETCH RATES AFTER FLOWABLE DEPOSITION OF SILICON-CARBON-AND-NITROGEN-CONTAINING LAYERS.” This application also claims the benefit of U.S. Provisional Application No. 61/567,738 by Underwood et al. filed Dec. 7, 2011 and titled “DOPING OF DIELECTRIC LAYERS.” Each of the above U.S. Provisional Applications is incorporated herein in its entirety for all purposes.

### BACKGROUND OF THE INVENTION

Semiconductor device geometries have dramatically decreased in size since their introduction several decades ago. Modern semiconductor fabrication equipment routinely produce devices with 45 nm, 32 nm, and 28 nm feature sizes, and new equipment is being developed and implemented to make devices with even smaller geometries. The decreasing feature sizes result in structural features on the device having decreased width. The widths of gaps and trenches on the device narrow such that filling the gap with dielectric material becomes more challenging. The depositing dielectric material is prone to clog at the top before the gap completely tills, producing a void or seam in the middle of the gap.

Over the years, many techniques have been developed to avoid having dielectric material clog the top of a gap, or to “heal” the void or seam that has been formed. One approach has been to start with flowable material that may be applied in a liquid phase to a spinning substrate surface (e.g., SOG deposition techniques). The flowable material can flow into and fill very small substrate gaps without forming voids or weak seams. The flowable material may contain silicon, carbon, oxygen and hydrogen. The flowable material is then cured to remove carbon and hydrogen thereby forming solid silicon oxide within the gaps.

The utility of gapfill silicon oxide often lies in its ability to electronically isolate adjacent transistors. Some process steps may benefit from the development of alternative materials which can still fill narrow gaps but possess low etch rates compared to silicon and/or silicon oxide. This and other needs are addressed in the present application.

### BRIEF SUMMARY OF THE INVENTION

Methods are described for forming and curing a gapfill silicon-and-carbon-containing layer on a semiconductor substrate. The silicon and carbon constituents may come from a silicon-and-carbon-containing precursor excited by a radical hydrogen precursor that has been activated in a remote plasma region. Exemplary precursors include 1,3,5-trisilapentane (H₃Si—CH₂—SiH₂—CH₂—SiH₃) as the silicon-and-carbon-containing precursor and hydrogen (H₂) as the hydrogen-containing precursor. The hydrogen-containing precursor may also be a hydrocarbon, such as acetylene (C₂H₂) or ethylene (C₂H₄). The hydrogen-containing precursor is passed through a remote plasma region to form plasma effluents (the radical hydrogen precursor) which are flowed into the substrate processing region. When the silicon-and-carbon-containing precursor combines with the plasma effluents in the substrate processing region, they form a flowable silicon-carbon-and-hydrogen-containing layer on the semiconductor substrate. In those parts of the substrate that are structured with high-aspect ratio gaps, the flowable silicon-carbon-and-hydrogen-containing layer may form in the gaps with significantly fewer voids and weak seams. Once the layer is formed, hydrogen content may be reduced by curing the substrate using disclosed cure treatments. Both the silicon-and-carbon-containing precursor and the radical hydrogen precursor may contain little or no oxygen. Lack of oxygen in the silicon-and-carbon-containing layer further decreases the beneficially low wet etch rate compared to silicon oxide and silicon.

Embodiments of the invention include methods of forming a silicon-and-carbon-containing layer on a semiconductor substrate. The methods include flowing a hydrogen-containing precursor into a remote plasma region to produce a hydrogen-containing plasma effluents. The methods further include combining a silicon-and-carbon-containing precursor with the hydrogen-containing plasma effluents in a substrate processing region which contains the semiconductor substrate. The methods further include forming a silicon-carbon-and-hydrogen-containing layer over the semiconductor substrate. The silicon-carbon-and-hydrogen-containing layer is initially flowable during deposition and the substrate processing region is plasma-free during formation of the silicon-carbon-and-hydrogen-containing layer. The methods further include treating the silicon-carbon-and-hydrogen-containing layer to form the silicon-and-carbon-containing layer on the semiconductor substrate.

Additional embodiments and features are set forth in part in the description that follows, and in part will become apparent to those skilled in the art upon examination of the specification or may be learned by the practice of the invention. The features and advantages of the invention may be realized and attained by means of the instrumentalities, combinations, and methods described in the specification.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 is a flowchart illustrating selected steps for making a silicon-and-carbon-containing layer according to embodiments of the invention.

FIG. 2 shows a substrate processing system according to embodiments of the invention.

FIG. 3A shows a substrate processing chamber according to embodiments of the invention.

FIG. 3B shows a gas distribution showerhead according to embodiments of the invention.

### DETAILED DESCRIPTION OF THE INVENTION

Methods are described for forming and curing a gapfill silicon-and-carbon-containing layer on a semiconductor substrate. The silicon and carbon constituents may come from a silicon-and-carbon-containing precursor excited by a radical hydrogen precursor that has been activated in a remote plasma region. Exemplary precursors include 1,3,5-trisilapentane (H₃Si—CH₂—SiH₂—CH₂—SiH₃) as the silicon-and-carbon-containing precursor and hydrogen (H₂) as the hydrogen-containing precursor. The hydrogen-containing precursor may also be a hydrocarbon, such as acetylene (C₂H₂) or ethylene (C₂H₄). The hydrogen-containing precursor is passed through a remote plasma region to form plasma effluents (the radical hydrogen precursor) which are flowed into the substrate processing region. When the silicon-and-carbon-containing precursor combines with the plasma effluents in the substrate processing region, they form a flowable silicon-carbon-and-hydrogen-containing layer on the semiconductor substrate. In those parts of the substrate that are structured with high-aspect ratio gaps, the flowable silicon-carbon-and-hydrogen-containing layer may form in the gaps with significantly fewer voids and weak seams. Once the layer is formed, hydrogen content may be reduced by curing the substrate using disclosed cure treatments. Both the silicon-and-carbon-containing precursor and the radical hydrogen precursor may contain little or no oxygen. Lack of oxygen in the silicon-and-carbon-containing layer further decreases the beneficially low wet etch rate compared to silicon oxide and silicon.

The formation of the initially-flowable silicon-carbon-and-hydrogen-containing layer may include significant concentrations of Si—H and C—H bonds. These bonds are reactive with the moisture and oxygen in air and a variety of etchants. This reactivity contributes to an increased rate of layer aging, contamination, and higher wet etch rates when the layers are exposed to hydrofluoric acid or phosphoric acid etchants. To address this, the silicon-carbon-and-hydrogen-containing layer may be cured to reduce the concentration of Si—H bonds while also increasing the concentration of Si—C bonds. After curing, the layer may be referred to herein as a silicon-and-carbon-containing layer. The curing may also reduce the concentration of C—H bonds in the silicon-and-carbon-containing layer. Curing techniques include exposing the flowable silicon-carbon-and-hydrogen-containing layer to a plasma, such as an inductively coupled plasma (e.g., an HDP-CVD plasma) or a capacitively-coupled plasma (e.g., a PE-CVD plasma). In some embodiments, the substrate processing region may be equipped with an in-situ plasma generating system to perform the plasma treatment following the deposition without removing the substrate from the chamber. Alternatively, the substrate may be transferred to a plasma treatment unit in the same fabrication system without breaking vacuum and/or being removed from system. This allows the curing step to occur before the initially deposited silicon-carbon-and-hydrogen-containing layer has been exposed to moisture and oxygen from the air.

Formed in this way, the cured silicon-and-carbon-containing layer may exhibit increased etch resistance to both conventional silicon oxide and silicon nitride dielectric etchants. For example, the silicon-and-carbon-containing layer may have better etch resistance to a hydrofluoric acid solution (HF) than a silicon oxide layer, and also have better etch resistance to a hot phosphoric acid solution than a silicon nitride layer. The increased etch resistance to both conventional oxide and nitride etchants allows these silicon-and-carbon-containing layers to remain intact during process routines that expose the substrate to both types of etchants.

### Exemplary Silicon-and-Carbon-Containing Layer Formation Process

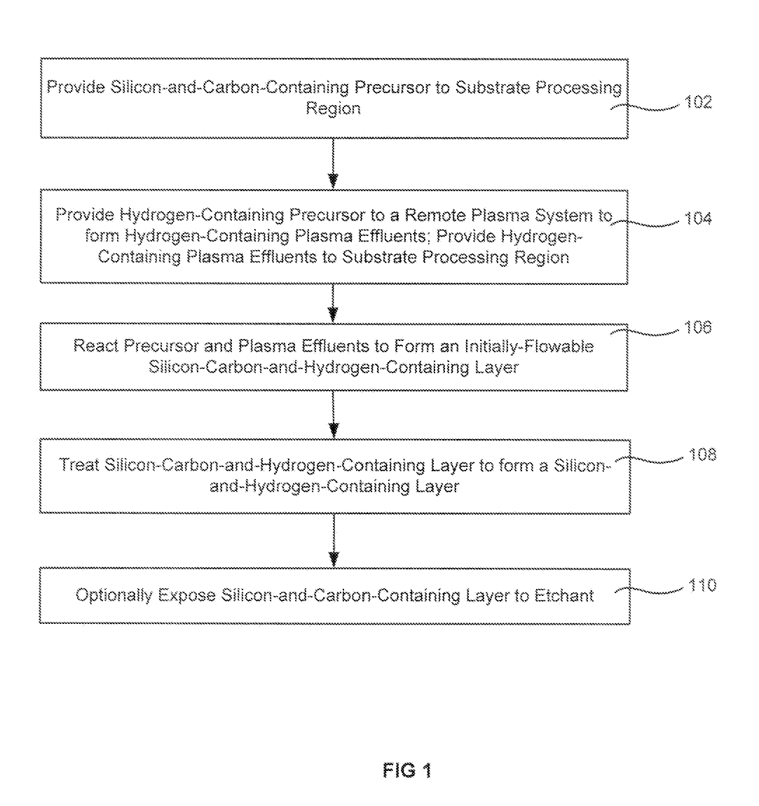

In order to better understand and appreciate the invention, reference is now made to FIG. 1 which is a flowchart showing selected steps in a method of forming a silicon-and-carbon-containing dielectric layer on a substrate according to embodiments of the invention. The method may include the step of providing a silicon-and-carbon-containing precursor 102 to a substrate processing region of a chemical vapor deposition chamber. The silicon-and-carbon-containing precursor may provide the silicon and carbon used in forming an initially-flowable silicon-carbon-and-hydrogen-containing layer as well as the silicon-and-carbon-containing layer formed later in the process. Exemplary silicon-and-carbon-containing precursors include 1,3,5-trisilapentane, 1,4,7 trisilaheptane, disilacyclobutane, trisilacyclohexane, 3-methylsilane, silacyclopentene, silacyclobutane, and trimethylsilylacetylene, among others:

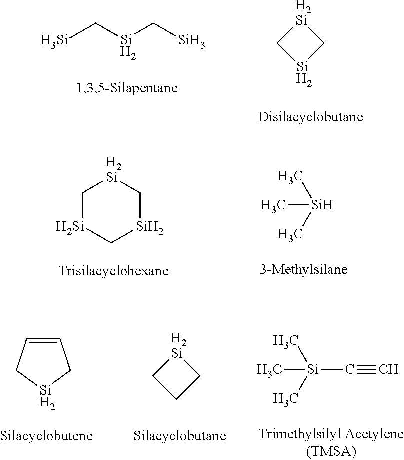

Additional exemplary silicon-and-carbon-containing precursors may include mono-, di-, tri-, tetra-, and penta-silanes where one or more central silicon atoms are surrounded by hydrogen and/or saturated and/or unsaturated alkyl groups. Examples of these precursors may include SiR₄, Si₂R₆, Si₃R₈, Si₄R₁₀, and Si₅R₁₂, where each R group is independently hydrogen (—H) or a saturated or unsaturated alkyl group. Specific examples of these precursors may include without limitation the following structures:

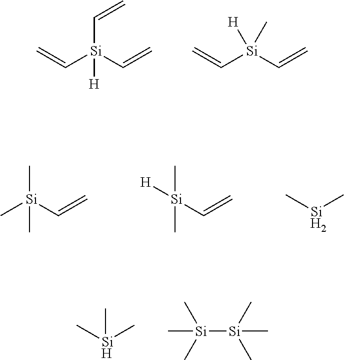

More exemplary silicon-containing precursors may include disilylalkanes having the formula R₃Si—[CR₂]ₓ—SiR₃, where each R is independently a hydrogen (—H), alkyl group (e.g., —CH₃, —CₘH₂ₘ₊₂, where m is a number from 1 to 10), unsaturated alkyl group (e.g., —CH═CH₂), and where x is a number for 0 to 10. Exemplary silicon precursors may also include trisilanes having the formula R₃Si—[CR₂]ₓ—SiR₂—[CR₂]_{y}—SiR₃, where each R is independently a hydrogen (—H), alkyl group (e.g., —CH₃, —CₘH₂ₘ₊₂, where m is a number from 1 to 10), unsaturated alkyl group (e.g., —CH═CH₂), and where x and y are independently a number from 0 to 10. Exemplary silicon-containing precursors may further include silylalkanes and silylalkenes of the form R₃Si—[CH₂]ₙ—[SiR₃]ₘ—[CH₂]ₙ—SiR₃, wherein n and m may be independent integers from 1 to 10, and each of the R groups are independently a hydrogen (—H), methyl (—CH₃), ethyl (—CH₂CH₃), ethylene (—CHCH₂), propyl (—CH₂CH₂CH₃), isopropyl (—CHCH₃CH₃), etc.

Exemplary silicon-containing precursors may further include polysilylalkane compounds may also include compounds with a plurality of silicon atoms that are selected from compounds with the formula R—[(CR₂)ₓ—(SiR₂)_{y}—(CR₂)_{z}]ₙ—R, wherein each R is independently a hydrogen (—H), alkyl group (e.g., —CH₃, —CₘH₂ₘ₊₂, where m is a number from 1 to 10)), unsaturated alkyl group (e.g., —CH═CH₂), or silane group (e.g., —SiH₃, —(Si₂H₂)ₘ—SiH₃, where m is a number from 1 to 10)), and where x, y, and z are independently a number from 0 to 10, and n is a number from 0 to 10. In disclosed embodiments, x, y, and z are independently integers between 1 and 10 inclusive. x and z are equal in embodiments of the invention and y may equal 1 in some embodiments regardless of the equivalence of x and z, n may be 1 in some embodiments.

For example when both R groups are —SiH₃, the compounds will include polysilylalkanes having the formula H₃Si—[(CH₂)ₓ—(SiH₂)_{y}—(CH₂)_{z}]ₙ—SiH₃. The silicon-containing compounds may also include compounds having the formula R—[(CR′₂)ₓ—(SiR″₂)_{y}—(CR′₂)_{z}]ₙ—R, where each R, R′, and R″ are independently a hydrogen (—H), an alkyl group (e.g., —CH₃, —CₘH₂ₘ₊₂, where m is a number from 1 to 10), an unsaturated alkyl group (e.g., —CH═CH₂), a silane group (e.g., —SiH₃, —(Si₂H)ₘ—SiH₃, where m is a number from 1 to 10), and where x, y and z are independently a number from 0 to 10, and n is a number from 0 to 10. In some instances, one or more of the R′ and/or R″ groups may have the formula —[(CH₂)ₓ—(SiH₂)_{y}—(CH₂)_{z}]—R′″, wherein R′″ is a hydrogen (—H), alkyl group (e.g., —CH₃, —CₘH₂ₘ₊₂, where m is a number from 1 to 10), unsaturated alkyl group (e.g., —CH═CH₂), or silane group (e.g., —SiH₃, —(Si₂H₂)ₘ—SiH₃, where m is a number from 1 to 10)), and where x, y, and z are independently a number from 0 to 10, and n is a number from 0 to 10.

Still more exemplary silicon-and-carbon-containing precursors may include silylalkanes and silylalkenes such as R₃Si—[CH₂]ₙ—SiR₃, wherein n may be an integer from 1 to 10, and each of the R groups are independently a hydrogen (—H), methyl (—CH₃), ethyl (—CH₂CH₃), ethylene (—CHCH₂), propyl (—CH₂CH₂CH₃), isopropyl (—CHCH₃CH₃), etc. They may also include silacyclopropanes, silacyclobutanes, silacyclopentanes, silacyclohexanes, silacycloheptanes, silacyclooctanes, silacyclononanes, silacyclopropenes, silacyclobutenes, silacyclopentenes, silacyclohexenes, silacycloheptenes, silacyclooctenes, silacyclononenes, etc. Specific examples of these precursors may include without limitation the following structures:

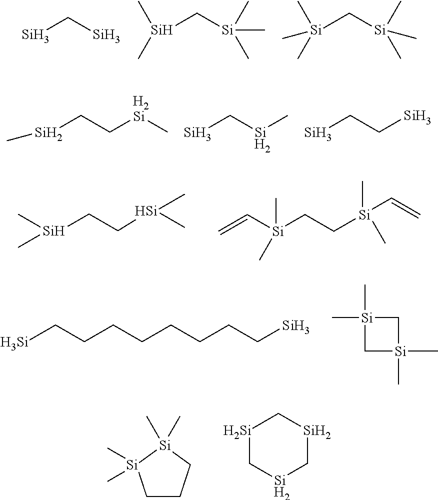

Exemplary silicon-and-carbon-containing precursors may further include one or more silane groups bonded to a central carbon atom or moiety. These exemplary precursors may include compounds of the formula H_{4-x-y}CX_{y}(SiR₃)ₓ, where x is 1, 2, 3, or 4, y is 0, 1, 2 or 3, each X is independently a hydrogen or halogen (e.g., F, Cl, Br), and each R is independently a hydrogen (—H) or an alkyl group. Exemplary precursors may further include compounds where the central carbon moiety is a C₂-C₆ saturated or unsaturated alkyl group such as a (SiR₃)ₓC═C(SiR₃)ₓ, where x is 1 or 2, and each R is independently a hydrogen (—H) or an alkyl group. Specific examples of these precursors may include without limitation the following structures:

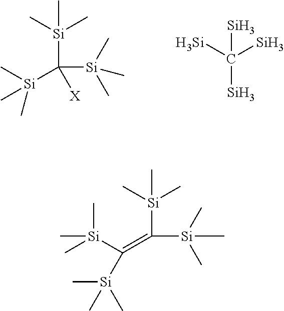

where X may be a hydrogen or a halogen (e.g., F, Cl, Br).

The flow rates of the silicon-and-carbon-containing precursor may be greater than or about 200 sccm, greater than or about 300 sccm or greater than or about 500 sccm in different embodiments. All flow rates given herein refer to a dual chamber substrate processing system processing two 3(X) mm diameter substrates on one side each. Single wafer systems would require half these flow rates and other wafer shapes/sizes/configurations would require flow rates scaled by the processed area. The silicon precursor may be mixed with a carrier gas before or during its introduction to the substrate processing region. A carrier gas may be an inactive gas that does not unduly interfere with the formation of the silicon-carbon-and-hydrogen-containing layer on the substrate. Examples of carrier gases include helium, neon, argon, xenon, and hydrogen (H₂), among other gases.

In embodiments where there is a desire to form a silicon-and-carbon-containing layer with low (or no) oxygen concentration, the silicon-and-carbon-containing precursor may be selected to be an oxygen-free precursor that contains no oxygen moieties. Reduced oxygen concentration in the silicon-and-carbon-containing layer may desirably reduce the etch rate of the layer. In these instances, conventional silicon CVD precursors, such as tetraethyl orthosilicate (TEOS) or tetramethyl orthosilicate (TMOS), would not be used as the silicon-and-carbon-containing precursor. Essentially devoid of oxygen may be used to describe precursors, plasma effluents and/or layers to allow for unavoidable or tolerable oxygen levels, e.g., originating from imperfect seals on gas handling systems and other hardware.

Similarly, the silicon-and-carbon-containing layer may be formed with little (or no) nitrogen concentration. Reduced nitrogen concentration in the silicon-and-carbon-containing layer may also desirably reduce the etch rate of the layer when exposed to, e.g., a hot phosphoric acid etch. Essentially devoid of nitrogen may be used to describe precursors, plasma effluents and/or layers to allow for unavoidable or tolerable nitrogen levels, e.g., originating from imperfect seals on gas handling systems and other hardware.

In addition to the silicon-and-carbon-containing precursor, hydrogen-containing plasma effluents are added to the substrate processing region 104. The hydrogen-containing plasma effluents interact with the silicon-and-carbon-containing precursor to form the initially-flowable silicon-carbon-and-hydrogen-containing layer. The hydrogen-containing plasma effluents are created by flowing a hydrogen-containing precursor through a remote plasma to form the hydrogen-containing plasma effluents. The hydrogen-containing precursor may include or consist essentially of hydrogen (H₂). The hydrogen-containing precursor may be accompanied by one or more additional gases such a helium, neon, argon, xenon, etc. The hydrogen-precursor may also contain carbon, in embodiments, that may provide a portion of the carbon constituent in the initially-flowable silicon-carbon-and-hydrogen-containing layer or the treated silicon-and-carbon-containing layer. In some instances the additional gases may also be at least partially dissociated and/or radicalized by the plasma, while in other instances they may act as a dilutant/carrier gas. The flow rate of the hydrogen-containing precursor may be greater than or about 300 sccm, greater than or about 500 sccm or greater than or about 700 sccm in different embodiments.

The semiconductor substrate used for depositing the silicon-carbon-and-hydrogen-containing layer and forming the silicon-and-carbon-containing layer may be a patterned semiconductor substrate and may have a plurality of gaps for the spacing and structure of device components (e.g., transistors) formed on the semiconductor substrate. The gaps may have a height and width that define an aspect ratio (AR) of the height to the width (i.e., H/W) that is significantly greater than 1:1 (e.g., 5:1 or more, 6:1 or more, 7:1 or more, 8:1 or more, 9:1 or more, 10:1 or more, 11:1 or more, 12:1 or more, etc.). In many instances the high AR is due to small gap widths of that range from about 90 nm to about 22 nm or less (e.g., less than 90 nm, 65 nm, 50 nm, 45 nm, 32 nm, 22 nm, 16 nm, etc.). Because the silicon-carbon-and-hydrogen-containing layer is initially-flowable, it can fill gaps with high aspect ratios without creating voids or weak seams around the center of the filling material. For example, a depositing flowable material is less likely to prematurely clog the top of a gap before it is completely filled to leave a void in the middle of the gap.

The hydrogen-containing precursor may be replaced or augmented by hydrocarbons such as acetylene (C₂H₂), ethylene (C₂H₄) and the like. The inventors have discovered that some additional carbon from hydrocarbons may be desirable, in embodiments of the invention, to increase the relative concentration of carbon in the initially-flowable silicon-carbon-and-hydrogen-containing layer and the treated silicon-and-carbon-containing layer. The hydrogen-containing plasma effluents may contain hydrogen (H₂) and/or hydrocarbons in disclosed embodiments. After treatment, the silicon-and-carbon-containing layer may contain at least 40% carbon, at least 43% carbon, at least 47% carbon and at least 49% carbon in embodiments of the invention.

The hydrogen-containing precursor may be energized by a plasma formed in a remote plasma system (RPS) positioned outside or inside the deposition chamber. The hydrogen-containing source may be exposed to the remote plasma where it is dissociated, radicalized, and/or otherwise transformed into the hydrogen-containing plasma effluents. The hydrogen-containing plasma effluents are then introduced to the substrate processing region and they mix for the first time with the separately introduced silicon-and-carbon-containing precursor. Exciting the silicon-and-carbon-containing precursor by contact with the hydrogen-containing plasma effluents, rather than directly by a plasma, forms unique deposition intermediaries. These intermediaries would not be present if a plasma were to directly excite the silicon-and-carbon-containing precursor. These deposition intermediaries may contain longer carbon chains which enable the silicon-carbon-and-hydrogen-containing layer to be initially-flowable unlike conventional silicon-and-carbon-containing (e.g. SiC) layer deposition techniques. The flowable nature during formation allows the layer to flow into narrow features before solidifying.

Alternatively (or in addition) to an exterior plasma region, the hydrogen-containing precursor may be excited in a plasma region inside the deposition chamber. This plasma region may be partitioned from the substrate processing region. The precursors mix and react in the substrate processing region to deposit the initially-flowable silicon-carbon-and-hydrogen-containing layer on the exposed surfaces of the substrate. Regardless of the location of the plasma region, the substrate processing region may be described as a “plasma free” region during the deposition process. It should be noted that “plasma free” does not necessarily mean the region is devoid of plasma. The borders of the plasma in the chamber plasma region are hard to define and may encroach upon the substrate processing region through, for example, the apertures of a showerhead if one is being used to transport the precursors to the substrate processing region. If an inductively-coupled plasma is incorporated into the deposition chamber, a small amount of ionization may even be initiated in the substrate processing region during a deposition without deviating from the scope of the present invention.

The substrate processing region may be described herein as “plasma-free” during the growth of the silicon-carbon-and-hydrogen-containing layer and during subsequent processes. “Plasma-free” does not necessarily mean the region is devoid of plasma. The borders of the plasma in the chamber plasma region are hard to define and may encroach upon the substrate processing region through the apertures in the showerhead. In the case of an inductively-coupled plasma, e.g., a small amount of ionization may be initiated within the substrate processing region directly. Furthermore, a low intensity plasma may be created in the substrate processing region without compromising the flowable nature of the forming layer. All causes for a plasma having much lower ion density than the chamber plasma region during the creation of the radical nitrogen precursor do not deviate from the scope of “plasma-free” as used herein.

Once in the substrate processing region, the hydrogen-containing plasma effluents and the silicon-and-carbon-containing precursor may react 106 to form an initially-flowable silicon-carbon-and-hydrogen-containing layer on the substrate. The temperature in the reaction region of the substrate processing region may be low (e.g., less than 100° C.) and the total chamber pressure may be about 0.1 Tort to about 10 Torr (e.g., about 0.5 to about 6 Torr, etc.) during the deposition of the silicon-carbon-and-hydrogen-containing layer. The temperature may be controlled in part by a temperature controlled pedestal that supports the substrate. The pedestal may be thermally coupled to a cooling/heating unit that adjust the pedestal and substrate temperature to, for example, about 0° C. to about 150° C.

The initially-flowable silicon-carbon-and-hydrogen-containing layer may be deposited on exposed planar surfaces a well as into gaps. The deposition thickness may be about 50 Å or more (e.g., about 1000 Å, about 150 Å, about 200 Å, about 250 Å, about 300 Å, about 350 Å, about 400 Å, etc.). The silicon-and-carbon-containing layer may be the accumulation of two or more silicon-and-carbon-containing layers that have undergone a treatment step before the deposition of the subsequent layer. For example, the silicon-and-carbon-containing layer may be a 1200 Å thick layer consisting of four deposited and treated 300 Å layers.

The flowability of the silicon-carbon-and-hydrogen-containing layer may be due to a variety of properties which result from mixing hydrogen-containing plasma effluents with the silicon-and-carbon-containing precursor. These properties may include a significant hydrogen component in the silicon-carbon-and-hydrogen-containing layer. The flowability does not rely on a high substrate temperature, therefore, the initially-flowable silicon-carbon-and-hydrogen-containing layer may fill gaps even on relatively low temperature substrates. During the formation of the silicon-carbon-and-hydrogen-containing layer, the substrate temperature may be below or about 400° C., below or about 300° C., below or about 200° C., below or about 150° C. or below or about 100° C. in embodiments of the invention.

As the silicon-carbon-and-hydrogen-containing layer reaches a desired thickness, the process effluents may be removed from the substrate processing region. These process effluents may include any unreacted hydrogen-containing plasma effluents and silicon-and-carbon-containing precursors, dilutent and/or carrier gases, and reaction products that did not deposit on the substrate. The process effluents may be removed by evacuating the substrate processing region and/or displacing the process effluents with non-deposition gases in the substrate processing region.

Following the formation of the initially-flowable silicon-carbon-and-hydrogen-containing layer and removal of the process effluents, a treatment 108 may be performed to reduce the concentration of Si—H and/or C—H bonds in the layer. As noted above, a reduction in the concentration of these bonds may be desired after the deposition to harden the layer and increase its resistance to etching, aging, and contamination, among other forms of layer degradation. Treatment techniques may include exposing the initially deposited layer to a plasma of one or more treatment gases such as helium, nitrogen, argon, etc. Treatment 108 may be accomplished by other means, including heating the substrate to a higher temperature without plasma, illuminating the deposition surface with ultraviolet (UV) light or directing an electron beam (e-beam) at the substrate. Any of the treatment techniques described herein may be used alone or in combination with any of the other techniques.

Following treatment 108, the initially-flowable silicon-carbon-and-hydrogen-containing layer becomes a silicon-and-carbon-containing layer. The silicon-and-carbon-containing layer may be essentially devoid of hydrogen in embodiments of the invention. Essentially devoid of hydrogen allow for trace amounts of hydrogen which do not significantly raise the wet etch rate ratio compared to thermally grown silicon oxide. Essentially devoid of hydrogen also allows for residual hydrogen deep inside trenches where a reduction in etch rate may be more tolerable. The silicon-and-carbon-containing layer may be silicon carbide in disclosed embodiments.

If a plasma is used, the plasma may be a capacitively-coupled plasma or a inductively-coupled plasma that is generated in-situ in the substrate processing region. For example, an inductively-coupled plasma treatment may be performed in an HDP-CVD deposition chamber, and a capacitively-coupled plasma may be performed in a plasma-enhanced CVD deposition chamber.

The plasma treatment may be done at comparable temperatures to the deposition of the silicon-carbon-and-hydrogen-containing layer. For example, the substrate may be about 300° C. or less, about 250° C. or less, about 225° C. or less, about 200° C. or less, etc. For example, the substrate may have a temperature of about 100° C. to about 300° C. The temperature of the substrate may be about 25° C. or more, about 50° C. or more, about 100° C. or more, about 125° C. or more, about 150° C. or more, etc. For example, the substrate temperature may have a range of about 25° C. to about 150° C. The pressure in the plasma treatment region may depend on the plasma treatment (e.g., CCP versus ICP), but typically ranges on the order of mTorr to tens of Torr.

Once treated, the silicon-carbon-and-hydrogen-containing layer becomes a silicon-and-carbon-containing layer. The silicon-and-carbon-containing layer may optionally be exposed to one or more etchants 110. The silicon-and-carbon-containing layer has a wet-etch-rate-ratio (WERR) that is lower than the silicon-carbon-and-hydrogen-containing layer. A WERR may be defined herein as the relative etch rate of the silicon-and-carbon-containing layer (e.g. Å/min) in a particular etchant (e.g., dilute HF, hot phosphoric acid) compared to the etch rate of a thermally-grown silicon oxide layer, silicon (e.g. polysilicon), or silicon nitride formed on the same substrate. A WERR of 1.0 (which also may be represented as 1:1) means the layer in question has the same etch rate as the comparison layer (silicon, silicon oxide or silicon nitride), while a WERR of greater than one (i.e. >1:1) means the layer etches at a faster rate than the comparison layer. The plasma treatment makes the silicon-and-carbon-containing layer more resistant to etching, thus reducing its WERR. The WERR of the silicon-and-carbon-containing layer may be less than 1:100, less than 1:200, or less than 1:500 in embodiments of the invention, relative to silicon, silicon oxide or silicon nitride.

The silicon-and-carbon-containing layers may have increased etch resistance (i.e. lower WERR levels) to wet etchants for both silicon oxides and silicon nitrides. For example, the plasma treatment of the silicon-carbon-and-hydrogen-containing layer may lower the WERR for hydrofluoric acid (HF), which is a conventional wet etchant for silicon oxide. The hydrofluoric acid may be a dilute hydrofluoric acid (DHF) bath or may be a buffered hydrofluoric acid bath in disclosed embodiments. The plasma treatment may also lower the WERR level for hot phosphoric acid, which is a conventional wet etchant for silicon nitride. Thus, the silicon-and-carbon-containing layers described herein may make good blocking and/or etch stop layers for etch processes that include both oxide and nitride etching steps.

### Exemplary Silicon Oxide Deposition System

Deposition chambers that may implement embodiments of the present invention may include high-density plasma chemical vapor deposition (HDP-CVD) chambers, plasma enhanced chemical vapor deposition (PECVD) chambers, sub-atmospheric chemical vapor deposition (SACVD) chambers, and thermal chemical vapor deposition chambers, among other types of chambers. Specific examples of CVD systems that may implement embodiments of the invention include the CENTURA ULTIMA® HDP-CVD chambers/systems, and PRODUCER® PECVD chambers/systems, available from Applied Materials. Inc. of Santa Clara, Calif.

Examples of substrate processing chambers that can be used with exemplary methods of the invention may include those shown and described in co-assigned U.S. Provisional Patent App. No. 60/803,499 to Lubomirsky et al, filed May 30, 2006, and titled “PROCESS CHAMBER FOR DIELECTRIC GAPFILL” the entire contents of which is herein incorporated by reference for all purposes. Additional exemplary systems may include those shown and described in U.S. Pat. Nos. 6,387,207 and 6,830,624, which are also incorporated herein by reference for all purposes.

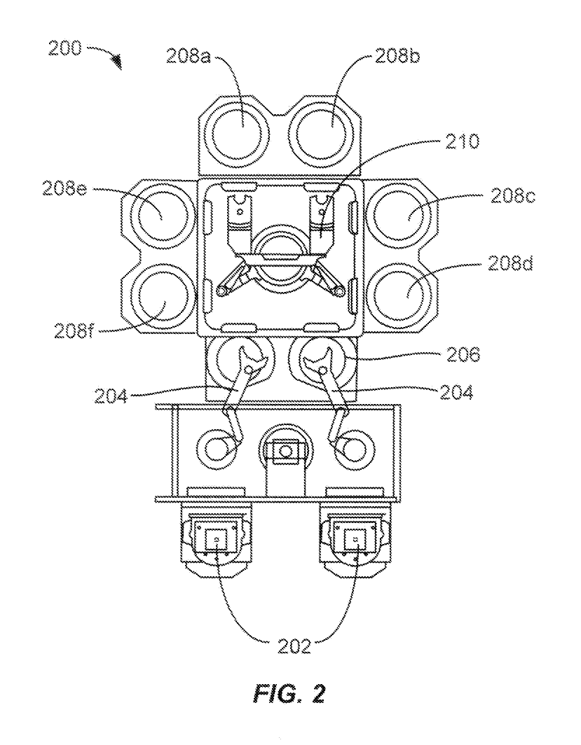

Embodiments of the deposition systems may be incorporated into larger fabrication systems for producing integrated circuit chips. FIG. 2 shows one such system 200 of deposition, baking and curing chambers according to disclosed embodiments. In the figure, a pair of FOUPs (front opening unified pods) 202 supply substrate substrates (e.g. 300 mm diameter wafers) that are received by robotic arms 204 and placed into a low pressure holding area 206 before being placed into one of the substrate processing chambers 208a-f. A second robotic arm 210 may be used to transport the substrate wafers from the holding area 206 to the substrate processing chambers 208a-f and back.

Substrate processing chambers 208a-f may include one or more system components for depositing, annealing, curing and/or etching a flowable dielectric layer on the substrate wafer. In one configuration, two pairs of the processing chamber (e.g., 208c-d and 208e-f) may be used to deposit the flowable dielectric material on the substrate, and the third pair of processing chambers (e.g., 208a-b) may be used to anneal the deposited dielectic. In another configuration, the same two pairs of processing chambers (e.g., 208c-d and 208e-f) may be configured to both deposit and anneal a flowable dielectric layer on the substrate, while the third pair of chambers (e.g., 208a-b) may be used for UV or E-beam curing of the deposited layer. In still another configuration, all three pairs of chambers (e.g., 208a-f) may be configured to deposit and cure a flowable dielectric layer on the substrate. In yet another configuration, two pairs of processing chambers (e.g., 208c-d and 208e-f) may be used for both deposition and UV or E-beam curing of the flowable dielectric, while a third pair of processing chambers (e.g. 208a-b) may be used for annealing the dielectric layer. Any one or more of the processes described may be carried out on chamber(s) separated from the fabrication system shown in different embodiments.

In addition, one or more of substrate processing chambers 208a-f may be configured as a wet treatment chamber. These process chambers include heating the flowable dielectric layer in an atmosphere that includes moisture. Thus, embodiments of system 200 may include wet treatment chambers 208a-b and anneal processing chambers 208c-d to perform both wet and dry anneals on the deposited dielectric layer.

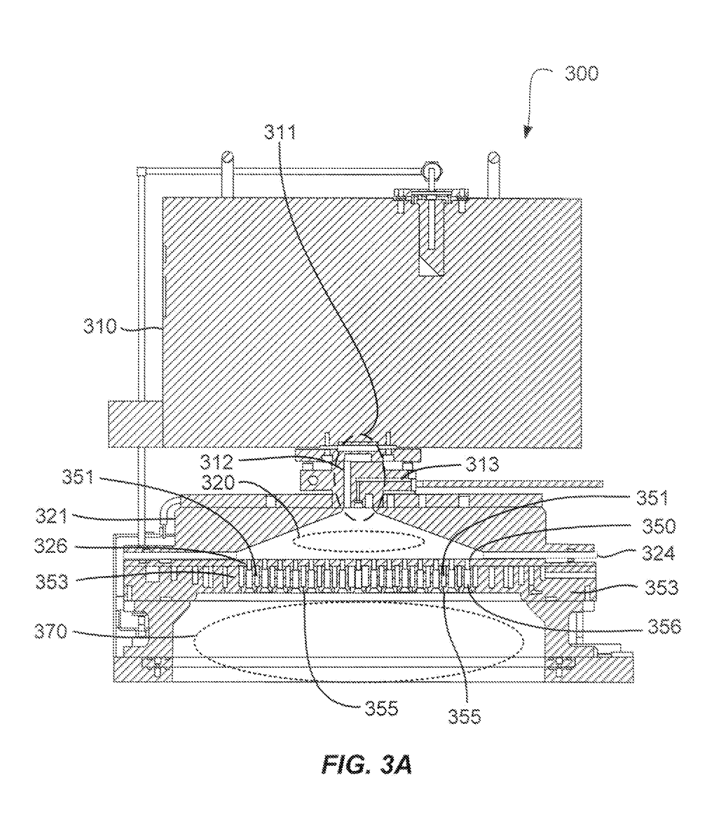

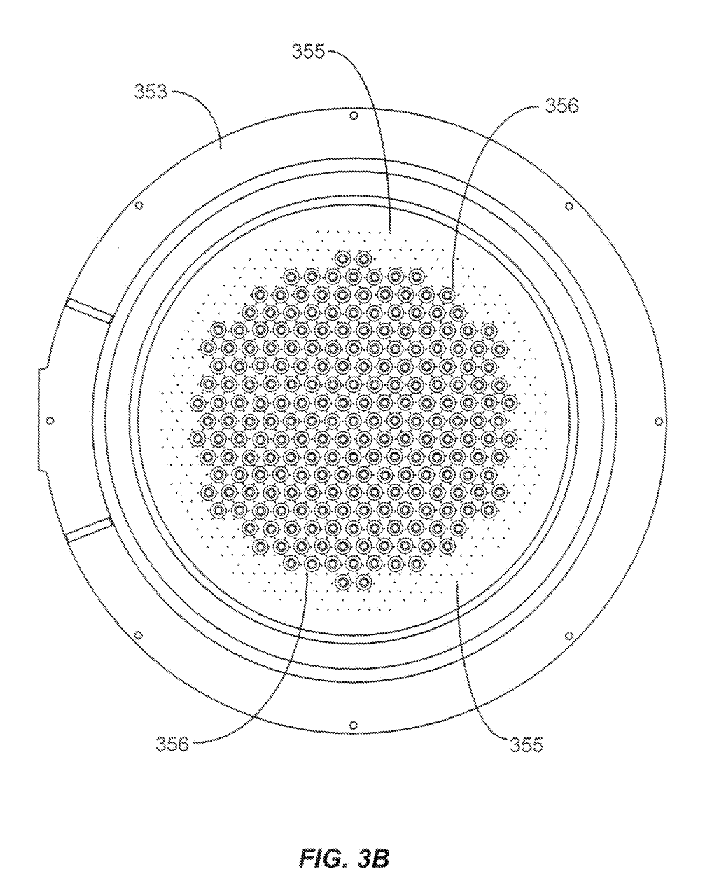

FIG. 3A is a substrate processing chamber 300 according to disclosed embodiments. A remote plasma system (RPS) 310 may process a gas which then travels through a gas inlet assembly 311. Two distinct gas supply channels are visible within the gas inlet assembly 311. A first channel 312 carries a gas that passes through the remote plasma system (RPS) 310, while a second channel 313 bypasses the RPS 310. The first channel 312 may be used for the process gas and the second channel 313 may be used for a treatment gas in disclosed embodiments. The lid (or conductive top portion) 321 and a perforated partition (showerhead 353) are shown with an insulating ring 324 in between, which allows an AC potential to be applied to the lid 321 relative to showerhead 353. The process gas travels through first channel 312 into chamber plasma region 320 and may be excited by a plasma in chamber plasma region 320 alone or in combination with RPS 310. The combination of chamber plasma region 320 and/or RPS 310 may be referred to as a remote plasma system herein. The perforated partition (also referred to as a showerhead) 353 separates chamber plasma region 320 from a substrate processing region 370 beneath showerhead 353. Showerhead 353 allows a plasma present in chamber plasma region 320 to avoid directly exciting gases in substrate processing region 370, while still allowing excited species to travel from chamber plasma region 320 into substrate processing region 370.

Showerhead 353 is positioned between chamber plasma region 320 and substrate processing region 370 and allows plasma effluents (excited derivatives of precursors or other gases) created within chamber plasma region 320 to pass through a plurality of through-holes 356 that traverse the thickness of the plate. The showerhead 353 also has one or more hollow volumes 351 which can be filled with a precursor in the form of a vapor or gas (such as a silicon-and-carbon-containing precursor) and pass through small holes 355 into substrate processing region 370 but not directly into chamber plasma region 320. Showerhead 353 is thicker than the length of the smallest diameter 350 of the through-holes 356 in this disclosed embodiment. In order to maintain a significant concentration of excited species penetrating from chamber plasma region 320 to substrate processing region 370, the length 326 of the smallest diameter 350 of the through-holes may be restricted by forming larger diameter portions of through-holes 356 part way through the showerhead 353. The length of the smallest diameter 350 of the through-holes 356 may be the same order of magnitude as the smallest diameter of the through-holes 356 or less in disclosed embodiments.

In the embodiment shown, showerhead 353 may distribute (via through-holes 356) process gases which contain oxygen, hydrogen and/or nitrogen and/or plasma effluents of such process gases upon excitation by a plasma in chamber plasma region 320. In embodiments, the process gas introduced into the RPS 310 and/or chamber plasma region 320 through first channel 312 may contain one or more of oxygen (O₂), ozone (O₃), N₂O, NO, NO₂, NH₃, NₓH_{y} including N₂H₄, silane, disilane, TSA and DSA. The process gas may also include a carrier gas such as helium, argon, nitrogen (N₂), etc. The second channel 313 may also deliver a process gas and/or a carrier gas, and/or a layer-curing gas (e.g. O₃) used to remove an unwanted component from the growing or as-deposited layer. Plasma effluents may include ionized or neutral derivatives of the process gas and may also be referred to herein as a radical-oxygen precursor and/or a radical-nitrogen precursor referring to the atomic constituents of the process gas introduced.

In embodiments, the number of through-holes 356 may be between about 60 and about 2000. Through-holes 356 may have a variety of shapes but are most easily made round. The smallest diameter 350 of through-holes 356 may be between about 0.5 mm and about 20 mm or between about 1 mm and about 6 mm in disclosed embodiments. There is also latitude in choosing the cross-sectional shape of through-holes, which may be made conical, cylindrical or a combination of the two shapes. The number of small holes 355 used to introduce a gas into substrate processing region 370 may be between about 100 and about 5000 or between about 500 and about 2000 in different embodiments. The diameter of the small holes 355 may be between about 0.1 mm and about 2 mm.

FIG. 3B is a bottom view of a showerhead 353 for use with a processing chamber according to disclosed embodiments. Showerhead 353 corresponds with the showerhead shown in FIG. 3A. Through-holes 356 are depicted with a larger inner-diameter (ID) on the bottom of showerhead 353 and a smaller ID at the top. Small holes 355 are distributed substantially evenly over the surface of the showerhead, even amongst the through-holes 356 which helps to provide more even mixing than other embodiments described herein.

An exemplary layer is created on a substrate supported by a pedestal (not shown) within substrate processing region 370 when plasma effluents arriving through through-holes 356 in showerhead 353 combine with a silicon-and-carbon-containing precursor arriving through the small holes 355 originating from hollow volumes 351. Though substrate processing region 370 may be equipped to support a plasma for other processes such as curing, no plasma is present during the growth of the exemplary layer.

A plasma may be ignited either in chamber plasma region 320 above showerhead 353 or substrate processing region 370 below showerhead 353. A plasma is present in chamber plasma region 320 to produce the radical nitrogen precursor from an inflow of a nitrogen-and-hydrogen-containing gas. An AC voltage typically in the radio frequency (RF) range is applied between the conductive top portion (lid 321) of the processing chamber and showerhead 353 to ignite a plasma in chamber plasma region 320 during deposition. An RF power supply generates a high RF frequency of 13.56 MHz but may also generate other frequencies alone or in combination with the 13.56 MHz frequency. The top plasma power may be greater than or about 11000 Watts, greater than or about 2000 Watts, greater than or about 3000 Watts or greater than or about 4000 Watts in embodiments of the invention, during deposition of the flowable film.

The top plasma may be left at low or no power when the bottom plasma in the substrate processing region 370 is turned on during the second curing stage or clean the interior surfaces bordering substrate processing region 370. A plasma in substrate processing region 370 is ignited by applying an AC voltage between showerhead 353 and the pedestal or bottom of the chamber. A cleaning gas may be introduced into substrate processing region 370 while the plasma is present.

The pedestal may have a heat exchange channel through which a heat exchange fluid flows to control the temperature of the substrate. This configuration allows the substrate temperature to be cooled or heated to maintain relatively low temperatures (from room temperature through about 120° C.). The heat exchange fluid may comprise ethylene glycol and water. The wafer support platter of the pedestal (preferably aluminum, ceramic, or a combination thereof) may also be resistively heated in order to achieve relatively high temperatures (from about 120° C. through about 1100° C.) using an embedded single-loop embedded heater element configured to make two fall turns in the form of parallel concentric circles. An outer portion of the heater element may run adjacent to a perimeter of the support platter, while an inner portion runs on the path of a concentric circle having a smaller radius. The wiring to the heater element passes through the stem of the pedestal.

The substrate processing system is controlled by a system controller. In an exemplary embodiment, the system controller includes a hard disk drive, a floppy disk drive and a processor. The processor contains a single-board computer (SBC), analog and digital input/output boards, interface boards and stepper motor controller boards. Various parts of CVD system conform to the Versa Modular European (VME) standard which defines board, card cage, and connector dimensions and types. The VME standard also defines the bus structure as having a 16-bit data bus and a 24-bit address bus.

The system controller controls all of the activities of the deposition system. The system controller executes system control software, which is a computer program stored in a computer-readable medium. Preferably, the medium is a hard disk drive, but the medium may also be other kinds of memory. The computer program includes sets of instructions that dictate the timing, mixture of gases, chamber pressure, chamber temperature, RF power levels, susceptor position, and other parameters of a particular process. Other computer programs stored on other memory devices including, for example, a floppy disk or other another appropriate drive, may also be used to instruct the system controller.

A process for depositing a layer (e.g. sequential deposition of an initially-flowable silicon-carbon-and-hydrogen-containing layer and then treating the layer and creating a silicon-and-carbon-containing layer) on a substrate can be implemented using a computer program product that is executed by the system controller. The computer program code can be written in any conventional computer readable programming language: for example, 68000 assembly language, C, C++, Pascal, Fortran or others. Suitable program code is entered into a single file, or multiple files, using a conventional text editor, and stored or embodied in a computer usable medium, such as a memory system of the computer. If the entered code text is in a high level language, the code is compiled, and the resultant compiler code is then linked with an object code of precompiled Microsoft Windows® library routines. To execute the linked, compiled object code the system user invokes the object code, causing the computer system to load the code in memory. The CPU then reads and executes the code to perform the tasks identified in the program.

The interface between a user and the controller is via a flat-panel touch-sensitive monitor. In the preferred embodiment two monitors are used, one mounted in the clean room wall for the operators and the other behind the wall for the service technicians. The two monitors may simultaneously display the same information, in which case only one accepts input at a time. To select a particular screen or function, the operator touches a designated area of the touch-sensitive monitor. The touched area changes its highlighted color, or a new menu or screen is displayed, confirming communication between the operator and the touch-sensitive monitor. Other devices, such as a keyboard, mouse, or other pointing or communication device, may be used instead of or in addition to the touch-sensitive monitor to allow the user to communicate with the system controller.

As used herein “substrate” may be a support substrate with or without layers formed thereon. The support substrate may be an insulator or a semiconductor of a variety of doping concentrations and profiles and may, for example, be a semiconductor substrate of the type used in the manufacture of integrated circuits. A layer of “silicon oxide” may include minority concentrations of other elemental constituents such as nitrogen, hydrogen, carbon and the like. In some embodiments, silicon oxide consists essentially of silicon and oxygen. The term “precursor” is used to refer to any process gas which takes part in a reaction to either remove material from or deposit material onto a surface. A gas in an “excited state” describes a gas wherein at least some of the gas molecules are in vibrationally-excited, dissociated and/or ionized states. A gas (or precursor) may be a combination of two or more gases (or precursors). A “radical precursor” is used to describe plasma effluents (a gas in an excited state which is exiting a plasma) which participate in a reaction to either remove material from or deposit material on a surface. A “radical-nitrogen precursor” is a radical precursor which contains nitrogen and a “radical-hydrogen precursor” is a radical precursor which contains hydrogen. The phrase “inert gas” refers to any gas which does not form chemical bonds when etching or being incorporated into a layer. Exemplary inert gases include noble gases but may include other gases so long as no chemical bonds are formed when (typically) trace amounts are trapped in a layer.

The term “trench” is used throughout with no implication that the etched geometry has a large horizontal aspect ratio. Viewed from above the surface, trenches may appear circular, oval, polygonal, rectangular, or a variety of other shapes. The term “via” is used to refer to a low aspect ratio trench which may or may not be filled with metal to form a vertical electrical connection. As used herein, a conformal layer refers to a generally uniform layer of material on a surface in the same shape as the surface, i.e. the surface of the layer and the surface being covered are generally parallel. A person having ordinary skill in the art will recognize that the deposited material likely cannot be 100% conformal and thus the term “generally” allows for acceptable tolerances.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the precursor” includes reference to one or more precursor and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A method of forming a silicon-and-carbon-containing layer on a semiconductor substrate, the method comprising:
flowing a hydrogen-containing precursor into a remote plasma region to produce a hydrogen-containing plasma effluents,
combining a silicon-and-carbon-containing precursor with the hydrogen-containing plasma effluents in a substrate processing region which contains the semiconductor substrate,
forming a silicon-carbon-and-hydrogen-containing layer over the semiconductor substrate, wherein the silicon-carbon-and-hydrogen-containing layer is initially flowable during deposition and the substrate processing region is plasma-free during formation of the silicon-carbon-and-hydrogen-containing layer, and
treating the silicon-carbon-and-hydrogen-containing layer to form the silicon-and-carbon-containing layer on the semiconductor substrate.

2. The method of claim 1 wherein the silicon-and-carbon-containing layer, the hydrogen-containing plasma effluents and the silicon-and-carbon-containing precursor are essentially devoid of oxygen.

3. The method of claim 1 wherein the silicon-and-carbon-containing layer is essentially devoid of hydrogen.

4. The method of claim 1 wherein the silicon-and-carbon-containing layer is silicon carbide.

5. The method of claim 1 wherein the silicon-and-carbon-containing layer, the hydrogen-containing plasma effluents and the silicon-and-carbon-containing precursor are essentially devoid of nitrogen.

6. The method of claim 1 wherein the hydrogen-containing plasma effluents and the silicon-and-carbon-containing precursor are essentially devoid of nitrogen.

7. The method of claim 1 wherein the silicon-and-carbon-containing precursor comprises 1,3,5-trisilapentane, 1,4,7-trisilaheptane, disilacyclobutane, trisilacyclohexane, 3-methylsilane, silacyclopentene, silacyclobutene, or trimethylsilylacetylene.

8. The method of claim 1 wherein the silicon-and-carbon-containing precursor comprises:
(i) SiR₄, Si₂R₆, Si₃R₈, Si₄R₁₀, or Si₅R₁₂, wherein each R group is independently hydrogen (—H) or a saturated or unsaturated alkyl group;
(ii) a silylalkane or silylalkene having the formula R₃Si—[CH₂]ₙ—SiR₃, wherein n may be an integer from 1 to 10, and each of the R groups are independently a hydrogen (—H), or a saturated or unsaturated alkyl group;
(iii) a silylalkane or silylalkene having the formula R₃Si—[CR₂]ₓ—SiR₂—[CR₂]_{y}—SiR₃, wherein x and y are independently an integer from 1 to 10, and each of the R groups are independently a hydrogen (—H), or a saturated or unsaturated alkyl group;
(iv) a silacycloalkane or silacycloalkene selected from the group consisting of silacyclopropanes, silacyclobutanes, silacyclopentanes, silacyclohexanes, silacycloheptanes, silacyclooctanes, silacyclononanes, silacyclopropenes, silacyclobutenes, silacyclopentenes, silacyclohexenes, silacycloheptenes, silacyclooctenes, and silacyclononenes;
(v) H_{4-x-y}CX_{y}(SiR₃)ₓ, where x is 1, 2, 3, or 4, y is 0, 1, 2 or 3, each X is independently a hydrogen or halogen (e.g., F, Cl, Br), and each R is independently a hydrogen (—H) or an alkyl group;
(vi) (SiR₃)ₓC═C(SiR₃)ₓ, where x is 1 or 2, and each R is independently a hydrogen (—H) or an alkyl group; or
(vii) R—[(CR′₂)ₓ—(SiR″₂)_{y}—(CR′₂)_{z}]—R, wherein each R, R′, and R″ are independently a hydrogen, an alkyl group, an unsaturated alkyl group, a silane group, or
—[(CH_{z})ₓ₁—(SiH₂)_{y1}—(CH₂)_{z1}]ₙ₁—R′″ wherein x1, y1 and z1 are independently a number from 0 to 10, and n1 is a number from 0 to 10,
wherein x, y and z are independently a number from 0 to 10, and n is a number from 0 to 10.

9. The method of claim 1 wherein the silicon-carbon-and-hydrogen-containing layer comprises Si—H bonds and treating the silicon-carbon-and-hydrogen-containing layer comprises reducing the concentration of Si—H bonds.

10. The method of claim 1 wherein the treating the silicon-carbon-and-hydrogen-containing layer comprises increasing the concentration of Si—C bonds.

11. The method of claim 1 wherein the treating of the silicon-carbon-and-hydrogen-containing layer comprises exposing the silicon-carbon-and-hydrogen-containing layer to a plasma.

12. The method of claim 11 wherein the plasma for treating the silicon-carbon-and-hydrogen-containing layer is located in the substrate processing region.

13. The method of claim 11 wherein the plasma is an inductively-coupled plasma or a capacitively-coupled plasma.

14. The method of claim 1 wherein the semiconductor substrate is patterned and has a trench having a width of about 50 nm or less.

15. The method of claim 1 wherein the WERR of the silicon-and-carbon-containing layer relative to silicon oxide is less than 1:100 in a hydrofluoric acid or phosphoric acid solution.

16. The method of claim 1 wherein the WERR of the silicon-and-carbon-containing layer relative to silicon is less than 1:100 in a hydrofluoric acid or phosphoric acid solution.

17. The method of claim 1 wherein the hydrogen-containing precursor comprises hydrogen.

18. The method of claim 1 wherein the temperature of the semiconductor substrate is below or about 400° C. while forming the silicon-carbon-and-hydrogen-containing layer.

19. The method of claim 1 wherein the hydrogen-containing precursor comprises at least one of C₂H₂ or C₂H₄.

20. The method of claim 1 wherein the silicon-and-carbon-containing layer contains at least 40% carbon.
